(19) United States
(12) Patent Application Publication
(10) Pub. No.: US 2004/0059970 A1
(43) Pub. Date: Mar. 25, 2004

(54) Multipurpose architecture and method for testing electronic logic and memory devices

(76) Inventors: Daniel Lloyd Wieberdink, Andover, MN (US); David Edwin Hesse, Minneapolis, MN (US); Philip A. Bailey, Marine on St. Croix, MN (US); Harold Eugene Hamilton, Minneapolis, MN (US)

Correspondence Address: John Veldhuis-Kroeze, WESTMAN CHAMPLIN & KELLY, Suite 1600 - International Centre, 900 South Second Avenue, Minneapolis, MN, 55402-3319, US

(21) Appl. No.: 10/154,578

(22) Filed: May 23, 2002

(51) Int. Cl. G01R 31/28

(52) U.S. Cl. 714/724

(57) ABSTRACT

A logic device test system having memory device testing capabilities includes vector storage memory which receives and stores test vectors from a system controller. An address sequencer controls retrieval of the test vectors from the vector storage memory. Data driver circuitry coupled to the vector storage memory receives the test vectors retrieved from the vector storage memory. The data driver circuitry further includes data drivers coupleable to and driving devices under test using the test vectors. The data driver circuitry further including driver formatting circuitry coupled to the data drivers and formatting test vectors provided to the data drivers. A plurality of format code save registers in the driver formatting circuitry save test vectors and selectively provide the test vectors to the data drivers for driving the devices under test.

### BACKGROUND OF THE INVENTION

The present invention relates to systems used in testing integrated circuits and, more particularly, to those designed to efficiently test both memory and logic type devices.

Historically, integrated circuits have been divided into two categories: memory devices, which simply store binary data in a very structured way; and logic devices, which process data in a more general way and may provide things like control functions, for example. Examples of memory device type integrated circuits include dynamic random access memories (DRAMs), synchronous DRAMs (SDRAMs), Direct RDRAMs (Rambus®), and others. Examples of logic device type integrated circuits include microprocessors, gate arrays and others.

Accordingly, equipment meant to test these devices tends to be divided along the same lines: memory device testers and logic device testers. The memory testers are typically designed with algorithmic type test pattern generators which can, for instance, perform real-time counter operations on subsets of the test patterns so that memory addresses presented to the device(s) under test can be incremented. Other operations would often be possible at high speed such as shifting, arithmetic operations, or bit scrambling, for example.

Equipment meant to test logic devices, on the other hand would typically sacrifice the algorithmic pattern generation capability for greater flexibility across the width of the pattern, or vector, being applied. Thus, instead of including the algorithmic test pattern generators, logic device test equipment typically includes a larger quantity of memory which stores the inputs (the test vectors) that will be applied to the device(s) under test, and the expected responses from the device(s) under test. This can be thought of as a finer grain architecture.

Since the logic tester architecture is more general than the memory tester architecture it can, of course, be used to test memory devices. The disadvantage being the fact that the number of vector steps (and therefore the pattern memory) required to test such devices would be directly proportional to the capacity, or storage size, of the memory device(s) in the tester. In some instances, the pattern memory must be approximately one hundred times deeper than the memory of the memory devices to be tested. This has been an obstacle to using the same test equipment to test both memory and logic devices.

The general need to have separate test equipment for testing memory devices and logic devices is problematic for manufacturers of integrated circuits for several reasons. For example, the need to purchase separate testers can increase the overall procurement costs, maintenance costs, space requirements, training and other financial or personnel related expenses incurred by the manufacturer. Further, as more and more integrated circuits follow the “system-on-a-chip” type of architecture in which logic devices (such as processors or other types) and associated memory are contained in the same chip, the previously mentioned differences between the two types of test equipment may render it difficult to test these system-on-a-chip devices in an economical, efficient and thorough manner.

Schemes have been developed to reduce the number of steps required to test memory devices on a logic tester. For instance, a test instruction which simply preserves the state of a particular signal output from the previous test step (if available in the test system) can be used in conjunction with subroutine call and return instructions to reduce the pattern size. With this approach, for every address bit moved into a subroutine the memory required for a typical test pattern is nearly halved. However, there are several disadvantages to this approach as well. First, no real patterns can be applied to the address bits which lie outside of the subroutine currently running. These bits are limited to the application of a steady state, or quiescent value, for the duration of the subroutine. This precludes the application of a surround-by-complement type pattern on these address bits, for example. Second, the current value of address bits is not really preserved in this type of scheme to the extent that a subroutine could be interrupted (by a refresh timeout for dynamic memory, for example) without risk of losing the address setting on those bits by the time control is returned to the subroutine. The interrupt service routine would have to maintain the same (Q) state on all the address lines, severely limiting the usefulness of the service routine. Third, if the pattern called for repeating a series of steps with complemented data, as is often the case, this would double the test memory required. Fourth, logic testers cannot accommodate multiplexed address and data buses, which is an obstacle to testing most memory devices in use today.

Consequently, a test equipment system which tests both memory and logic integrated circuit devices, while addressing one or more of the above-described problems or other problems not discussed, would be a significant improvement in the art.

### SUMMARY OF THE INVENTION

The present invention overcomes one or more of the above discussed problems, or other problems not discussed, by providing for the storage on a test pin-by-test pin basis of formatting codes (which produce positive or negative pulses, test for high, or low, etc.) in special registers for later use by subroutines. These registers are used in the test microcode much the same as variables would be used in a software program as opposed to constant values. They can be loaded and/or used on-the-fly at any microcode step in the test program. A global (non pin-by-pin) control field in the microcode controls the loading of the registers. When the contents of the registers are to be driven to the test pin instead of a fixed format code, a letter (A, B, C, or D) is inserted in the microcode for that pin designating which register's data is to be used to supply format data for driving the pin under test for that step. Since the preexisting data path for format codes is used to supply data into the format code save registers, very little overhead is created in the test system. The registers also provide for the preservation of address information while an interrupt (for dynamic RAM refresh, for instance) is being serviced.

### BRIEF DESCRIPTION OF THE DRAWINGS

FIG. 1 is a block diagram of a test system or tester in accordance with the present invention, which allows efficient testing of both logic and memory devices.

FIG. 2 shows a block diagram of the test system or tester shown in FIG. 1, which illustrates additional features in accordance with an illustrative embodiment of the present invention.

FIG. 3 is an enlarged view of the test system electronics shown in FIG. 2.

FIG. 4 is a table illustrating various codes used in an illustrative embodiment of the present invention.

FIG. 5 is a block diagram illustrating an application specific integrated circuit, comprising a portion of the data drivers shown in FIG. 3, in which various aspects of the present invention can be implemented in one illustrative embodiment.

FIG. 6 shows the format of the microcode bits which control the memory testing features.

### DETAILED DESCRIPTION OF AN ILLUSTRATIVE EMBODIMENT

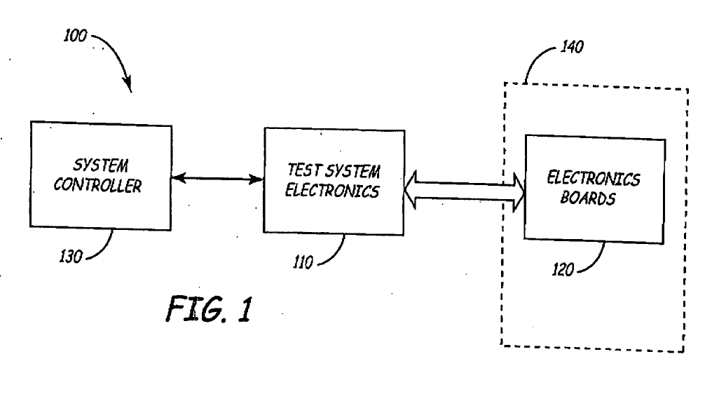

FIG. 1 is a block diagram illustrating a logic and memory test system 100 in accordance with illustrative embodiments of the present invention. Test system 100, which can be a tester or test equipment capable of testing integrated circuit memory devices, integrated circuit logic devices, and hybrid integrated circuit devices which contain significant quantities of memory and logic, such as a system-on-a-chip type integrated circuit. For example, system 100 can be a logic and memory test system such as the one sold by MICRO CONTROL COMPANY, having offices at 7956 Main Street N.E., Minneapolis, Minn. 55432, U.S.A., under the product name ABES-V™. In some embodiments, test system 100 includes at least system controller 130 and test system electronics 110, but can include other components such as a burn-in oven 140 and electronics boards 120. In alternative embodiments, oven 140 and electronics boards 120 are not part of system 100, but can be provided separately for use with system 100. Further, in some embodiments, system controller 130 can be omitted, and test system 100 can include only test system electronics 110. In these instances, a suitably programmed system controller 130 would typically be provided separately from test system electronics 110, but functions with test system electronics substantially as described below. Many other embodiments of system 100 of the present invention can be realized.

In some embodiments, for example one including all of the components shown in FIG. 1, test system 100 is an automatic burn-in and environmental system which provides both burn-in and electronic testing for both very-large-scale-integration (VLSI) logic devices and memory devices. Temperature, voltage and pattern stresses can be applied and device functionality can be tested while the devices are mounted on electronics boards 120 positioned within oven 140. As such, system 100 supports efficient “burn-in-with-test” of microprocessors, gate arrays, DRAMs, SDRAMs, Direct RDRAMs (Rambus®), as well as other logic and/or memory devices.

System controller 130 can be a microcomputer used to control test system electronics 110 and numerous aspects of the test requirements. For example, system controller 130 can be a suitably programmed personal computer operating using the Microsoft Windows NT/2000® operating system. An operator of system 100 can use system controller 130 to adjust temperature, voltage, test patterns, device timing, data formatting, and power supply systems, as well as to control atmosphere within burn-in oven 140 for high-temperature burn-in testing. System controller 130 can also collect output data from the devices under test (mounted on electronics boards 120). Test vectors are created in system controller 130 and provided to test system electronics 110 for use in testing the memory or logic devices mounted on electronics boards 120.

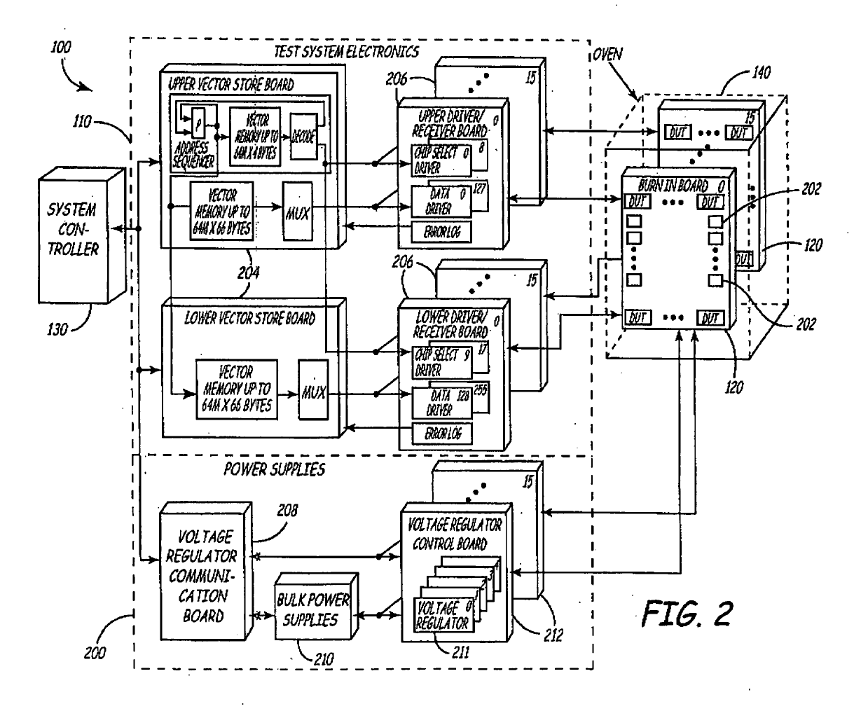

FIG. 2 is a block diagram illustrating portions of system 100 in greater detail. As shown in FIG. 2, system 100 can also include power supply circuitry 200 which, under the control of system controller 130, provides power to integrated circuit devices 202 mounted on boards 120 and positioned in oven 140. In the embodiment illustrated in FIG. 2, which is provided as a non-limiting example, power supply circuitry 200 includes a voltage regulator communication board 208 coupled to system controller 130 for receiving commands from system controller 130, and for providing feedback to system controller 130. Bulk power supplies 210 and voltage regulators 211 (mounted on voltage regulator control board 212) provide power to the devices 202 under test. Typically, the power supplies are protected by fuses and programmable limits, and are continuously monitored by system controller 130 for faults. Any failure of a power supply then activates an alarm and causes the associated burn-in board 120 slot to shut down immediately. Such a power failure also causes the system to record which power supply failed, which oven was effected (in embodiments containing more than one oven), the time of failure, etc. Again, the present invention is not limited to any particular power supply configuration, nor to a particular error reporting or automatic shut-down procedure.

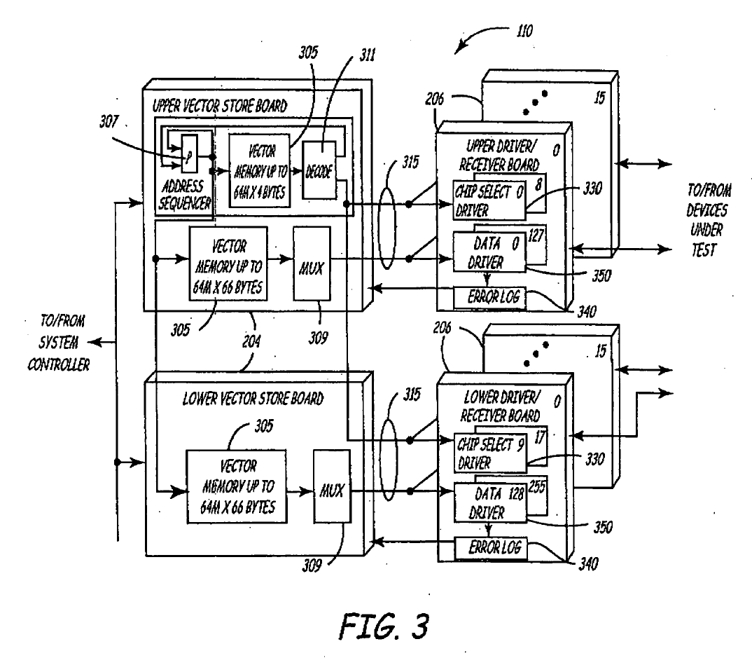

Also as shown in FIG. 2, test system electronics 110 includes one or more vector store boards 204 and one or more driver/receiver boards 206. These boards receive test vectors downloaded from system controller 130, and utilize these test vectors to test devices 202. The methods and apparatus of the present invention are discussed with reference to an application-specific integrated circuit (ASIC) positioned on the driver/receiver board(s) 206 as discussed below in greater detail with reference to FIG. 3.

FIG. 3 is a block diagram illustrating test system electronics 110 in an enlarged view according to one example embodiment of the invention. As shown in FIGS. 2 and 3, in one embodiment test system electronics 110 includes separate upper and lower vector store boards 204, but in other embodiments more or fewer vector store boards can be included. Test vectors from system controller 130 are downloaded into vector memory 305 on the vector store boards. After downloading the test vectors, the system controller 130 instructs address sequencer 307 to start reading data out of the memory 305 and applying it (via multiplexors 309) to the device under test (positioned on boards 120 as shown in FIG. 2). Multiplexors (MUX) 309 are used for time multiplexing in many embodiments because, with four bits for each test vector, and with a large number of driver channels (for example 256 driver channels on backplane 315-128 per vector store board in one embodiment), a very large number of pins (four times the number of driver channels) would be necessary on the backplane.

Vector memory 305 is also coupled to decode circuitry 311 which is an instruction decoder for controlling jumps, subroutine calls, etc. Although shown as three separate blocks in FIGS. 2 ad 3, vector memory 305 can be a single memory device.

Under the control of address sequencer 307, the test vectors are sent via backplane 315 to the driver/receiver boards 206. As shown in FIG. 3, driver/receiver boards 206 include multiple pairs of upper and lower driver/receiver boards, one pair for each burn-in board containing devices to be tested. Since in some embodiments 256 or more bi-directional signals are to be provided from the driver/receiver boards, division of the driver/receiver boards into upper and lower board pairs can be helpful in providing room for all of the necessary electronics. However, in other embodiments, it is not necessary that the driver/receiver boards be embodied in upper and lower board pairs. Instead, the upper and lower driver/receiver boards can be combined into a single board or separated into more than two boards. Further, in some embodiments, one driver/receiver board or board pair can be used to drive devices on more than one burn-in board.

Driver/receiver boards 206 include chip select drivers 330 which allow the selection of a particular one of many devices which are mounted on boards 120 and bused together to reduce the number of pins required for access. Error log circuit 340 logs errors in the responses of the devices under test, and provides this information back to system controller 130.

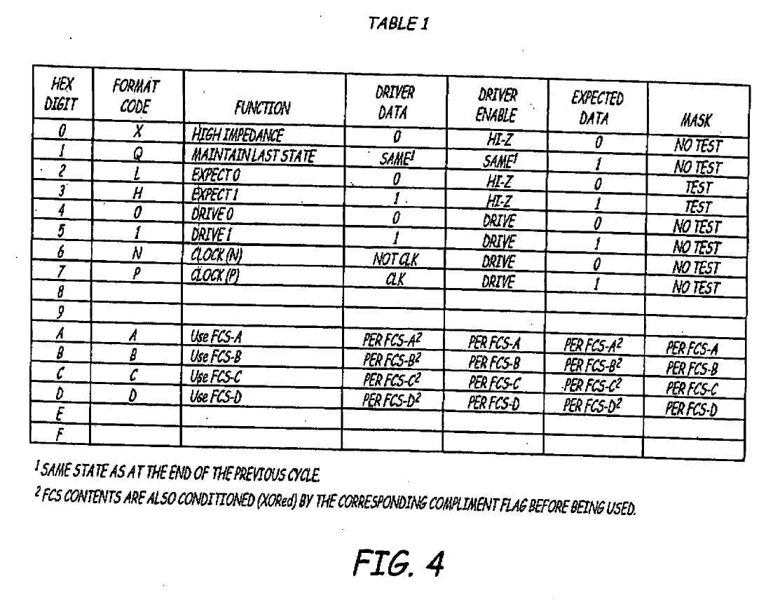

Driver/receiver boards 206 receive the serialized format 4-bit codes from vector store boards 204 for each driver and instruct the data driver 350 to do one of a number of operations (up to sixteen in 4-bit code embodiments) during that particular cycle. In one embodiment, twelve operations are as shown in Table 1 included in FIG. 4. These operations can be any of many types of operations suited for the particular test system. Examples of these types of operations are provided below.

Each format code specifies the actions of its associated pin on the Driver/Receiver Board. Three of the four bits in the format code are used to produce the first eight format codes shown in TABLE 1. The fourth bit is used to produce the four new format codes which support the architectural enhancements for testing memory devices discussed herein. A brief description of each code shown in Table 1 follows:

Code X (hex digit 0) places the driver in a high impedance state. Code Q (hex digit 1) directs the driver to maintain the same level as at the end of the previous test step. Codes L and H (hex digits 2 and 3) direct the receiver to test the signal from the device under test (DUT) for an expected 0 (Code L) or an expected 1 (code H). Codes 0 and 1 (hex digits 4 and 5) direct the driver to output a 0 or 1 respectively, and Codes N and P (hex digits 6 and 7) provide clocking for the DUT or, in the case of memory testing, they can provide surround-by-complement patterns for DUT address and/or data pins. The formatter develops the signal to be applied to the driver from the format code and one of a number of timing sets available to the driver circuit. Codes X, Q, L, H, 0, 1, N and P are conventional codes common to many test systems. The additional four codes (A, B, C and D) allow for an architecture which conveniently and efficiently tests both memory devices and logic devices.

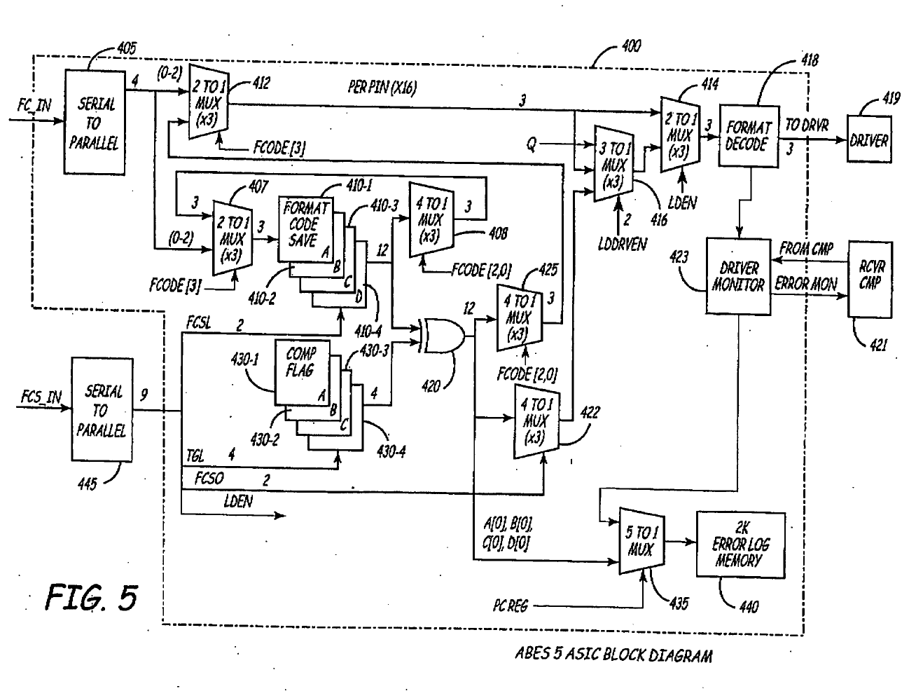

FIG. 5 is a block diagram illustrating a data driver ASIC 400 from driver/receiver boards 206 in greater detail. Data driver ASIC 400 is part of data driver circuitry 350 (along with a conventional driver 419). Methods and apparatus of the present invention are at least partially implemented in data driver ASIC 400 in some embodiments, though discrete circuitry and/or suitably programmed processing devices could also be used to implement these aspects of the invention.

Serial to parallel converter 405 of ASIC 400 receives as an input from vector store board 204 a serialized format code FC_IN, and converts it to a 4-bit parallel signal which dictates the selection of one of the up to sixteen operations discussed above. The lower three bits of the 4-bit format codes can be provided to (via multiplexer 407) and stored in one of the four 3-bit format code save registers 410. The fourth bit of the 4-bit format code controls multiplexers 407 and 412 to enable the use of the stored format codes. The four format code save registers A, B, C and D are denoted 410-1, 410-2, 410-3 and 410-4, respectively. The format codes can also be provided directly to (via multiplexors 412, 414 and 416) format decoder 418 for decoding, and ultimately directly to the driver 419 for controlling testing during a particular cycle in a more conventional manner.

Format decoder 418 decodes or interprets the format code to determine the corresponding instructions, and directs the operation of the driver 419 and of the receiver comparators 421 (via driver monitor 423). Driver 419 and receiver comparators 421 are coupled to devices under test (devices 202 shown in FIG. 2) to drive the devices and to monitor actual and expected result comparisons. When the format codes are provided directly to the driver 419 in this fashion, aspects of the present invention which rely upon format code save registers 410 are not in use. In other words, ASIC 400 is configured to allow either straight or direct format control using received format code inputs, or to allow format control using a format code saved in one of save registers 410. When relying upon a format code stored in one of format code save registers, this format code is provided to format decoder 418, and ultimately to the driver 419, via exclusive-or (XOR) gate 420 and multiplexors 425, 412 and 414.

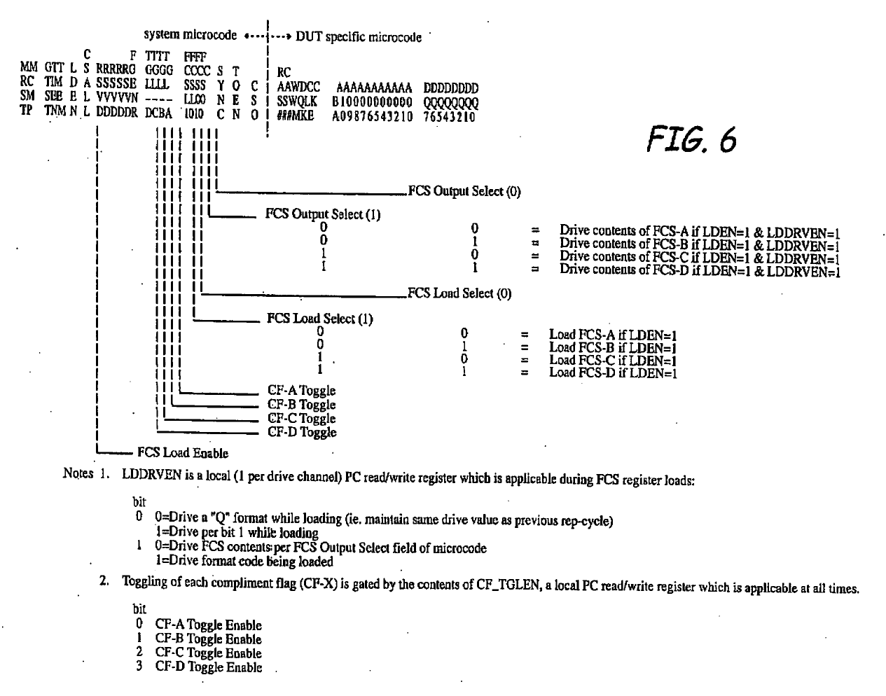

During any test step, any of the codes described above (or similar codes in other embodiments), or the contents of any format code save register 410 (via MUX 407 and MUX 408) can be loaded into one of the four format code save registers 410 if desired. The existence of these registers allows the system to perform memory testing efficiently, without the need for algorithmic generators. Whether or not the code that appears at any given test step is to be loaded into one of these registers, and the selection of which one to load, is controlled by the LDEN and FCSL fields of the control instruction for that test step (FIG. 6). In addition, whether or not the code should also be driven to the device under test (DUT) via MUX 416 and MUX 414 during a load instruction is controlled on a pin by pin basis, by a configuration register initialized before the start of the test (LDDRVEN in FIG. 5). This gives the option of allowing clock signals to continue uninterrupted while addresses are being updated, for instance. If the code being loaded is not to be simultaneously driven to the device under test, that pin can drive according to a previously saved code from one of the four registers 410 (as selected by the FCSO field of the control instruction for that test step) via MUX 422, or maintain the last state (same as a Q format) during the load.

Codes A, B, C & D are inserted in the test steps in much the same way variables would be used in a higher level software program. Using variables makes the code more flexible and allows sections or routines of code to be reused, reducing the number of lines of code required to accomplish a given task. Wherever one of these four codes appears in the test program for a given pin, the current contents of that register are routed via MUX 412 and MUX 425 to the formatter (format decoder) 418 to be used to develop the signal to be applied to the driver 419. These four codes can be intermixed with each other or any of the fixed codes (0 through 7) on a pin by pin basis in any test step. For each format code save register 410, there exists a corresponding complement flag 430 (flags 430-1 through 430-4 are shown) which further conditions the data before use by the formatter 418 to apply to the driver. If this flag is set, an L will be treated as an H, and an H as an L; an N will be treated as a P, and so on. Codes X and Q are not affected by the complement flags (an X will be treated as an X, and a Q as a Q, regardless of the state of the complement flag). The value of the flag is toggled by using the “toggle” or “TGL” field of the control instruction. Note that the contents of the corresponding register 410 are not affected, only the value of the complement flag is toggled.

Other components shown in FIG. 5 provide additional features which can be used with the present invention. For example, MUX 435 and error log memory 440 are used to save the contents (memory address location) of a format code save register 410 in order to record where a particular error occurred in a device under test. Serial-to-parallel converter 445 and input FCS_IN are used to load registers 410. FCS_IN also controls the LDEN bit, which is used to control when information (i.e., addresses or data) is saved in or read from a format code save register.

These architectural extensions essentially take advantage of the fact that the algorithms that a test program might employ (to generate addresses, for instance) really do not need to be executed over and over in real time as the test executes. But rather, they can be executed just once as a pre-processing, or compilation, step. In other words, the simpler algorithms can be implemented in software rather than hardware.

Thus it is seen that we have disclosed a new and more versatile architecture for testing integrated circuits. Furthermore, the additional space and cost encountered by use of large memory arrays in the tester has been avoided.

In summary, the present invention provides for the storage on a test pin-by-test pin basis of formatting codes (which produce positive or negative pulses, test for high, or low, etc.) in special registers for later use by subroutines. These registers are used in the test microcode much the same as variables would be used in a software program as opposed to constant values. They can be loaded and/or used on-the-fly at any microcode step in the test program. A global (non pin-by-pin) control field in the microcode controls the loading of the registers. When the contents of the registers are to be driven to the test pin instead of a fixed format code, a letter (A, B, C, or D) is inserted in the microcode for that pin designating which register's data is to be used to supply data into the format code saving registers. Very little overhead is created in the test system. This allows the efficient testing of memory devices on a logic device type tester, without the use of conventional algorithmic type test pattern generators. The registers also provide for the preservation of address information while an interrupt (for dynamic RAM refresh, for instance) is being serviced, and allow for multiplexed addresses which are typically needed in memory devices. While testing memory devices having multiplexed address inputs, a first piece of the address (for example a row address) can be stored in a first format code save register, while a second piece of the address (for example a column address) can be saved in a second format code save register. Additional pieces of an address can be saved in additional format code save registers.

Logic testers, which are vector driven, have not previously possessed the memory device testing capabilities of the testers of the present invention. Thus, if a conventional logic tester is addressing a particular address when a refresh interrupt occurs, the logic tester would return from the refresh and the particular memory location would have been lost, with no way to get that piece of information back again. Thus, in the present invention, the format code save registers hold these addresses during refreshes and other interrupts, so that when control is returned after the interrupt the information is available by referencing that register again. This allows memory devices to be tested on a logic tester.

Although the present invention has been described with reference to a preferred embodiment, workers skilled in the art will recognize that changes may be made in form and detail without departing from the spirit and scope of the invention. For instance, transfer of format codes from one format code save register to another during test execution may not be required, in which case MUX 407 and MUX 408 could be omitted. As another example, the number of format code save registers can be increased or decreased from the four discussed above. Accordingly, the present invention is not limited by the specific structural components used in describing the illustrative embodiment.

What is claimed is:

1. A logic device test system having memory device testing capabilities, the logic device test system comprising:
vector storage memory which receives and stores test vectors from a system controller;
an address sequencer which controls retrieval of the test vectors from the vector storage memory;
data driver circuitry coupled to the vector storage memory and receiving the test vectors retrieved from the vector storage memory, the data driver circuitry further including:
data drivers coupleable to and driving devices under test using the test vectors; and
driver formatting circuitry coupled to the data drivers and formatting test vectors provided to the data drivers, the driver formatting circuitry including a plurality of format code save registers which save test vectors, the test vectors saved in the plurality of format code save registers being selectively provided to the data drivers for driving the devices under test.

2. The logic device test system of claim 1, wherein the test vectors include addresses of memory locations in the devices under test.

3. The logic device test system of claim 2, wherein the format code save registers save addresses of currently tested memory locations in the devices under test.

4 The logic device test system of claim 3, wherein the devices under test include memory devices having multiplexed address inputs.

5 The logic device test system of claim 4, wherein a first piece of the address is stored in a first format code save register and a second piece of the address is stored in a second format save code register.

6. The logic device test system of claim 3, wherein the driver formatting circuitry is configured to selectively provide the addresses of the currently tested memory locations from one of the format code save registers to the data drivers.

7. The logic device test system of claim 6, wherein the driver formatting circuitry is configured to provide the addresses of a currently tested memory location from one of the format code save registers to the data drivers upon a return from an interrupt subroutine so that the currently tested memory location is not lost.

8. The logic device test system of claim 6, wherein the driver formatting circuitry is further configured to selectively provide addresses of memory locations in the devices under test to the data drivers directly from the vector storage memory, bypassing the format code save registers.

9. The logic device test system of claim 8, wherein the data formatting circuitry further comprises error log memory, coupled to the format code save registers, wherein the data formatting circuitry is configured to provide the address of a currently tested memory location from one of the format code save registers to the error log memory to record where a particular error occurred in a device under test.

10. The logic device test system of claim 1, wherein the test vectors stored in the format code save registers include data to be applied to the device under test.

11. The logic device test system of claim 10, wherein the format code save registers save data to be applied to currently tested memory locations in the devices under test.

12. The logic device test system of claim 11, wherein the driver formatting circuitry is configured to selectively provide the data to be applied to currently tested memory locations from one of the format code save registers to the data drivers.

13. The logic device test system of claim 12, wherein the driver formatting circuitry is further configured to selectively provide data to be applied to currently tested memory locations in the devices under test to the data drivers directly from the vector storage memory, bypassing the format code save registers.

14. The logic device test system of claim 13, wherein the data formatting circuitry further comprises error log memory, coupled to the format code save registers, wherein the data formatting circuitry is configured to provide the data applied to a currently tested memory location from one of the format code save registers to the error log memory when a particular error occurs in a device under test.

15. The logic device test system of claim 1, wherein the driver formatting circuitry further includes complementing circuitry coupled to the format save code registers and selectively complementing at least a portion of the test vectors stored in the format code save registers for application to the device under test.
